(19) United States
(12) Patent Application Publication
(10) Pub. No.: US 2026/0246265 A1
(43) Pub. Date: Aug. 20, 2026

(54) VOLTAGE CLAMP CIRCUIT AND POWER AMPLIFIER

(71) Applicant: Murata Manufacturing Co., Ltd., Nagaokakyo-shi (JP)

(72) Inventor: Yuri HONDA, Nagaokakyo-shi (JP)

(21) Appl. No.: 19/535,514

(22) Filed: Feb. 10, 2026

(30) Foreign Application Priority Data
Feb. 17, 2025 (JP) 2025-023687

(51) Int. Cl. H02H 9/04; H03F 3/24

(52) U.S. Cl. CPC H02H 9/04; H03F 3/245

(57) ABSTRACT

A first diode circuit includes first diodes connected in multiple stages and has an anode-side node connected to an output node of a high-frequency amplification circuit. A second diode's anode is connected to a cathode-side node of the first diode circuit. A first impedance element is connected between the second diode's cathode and a reference potential. A first current source is connected to a node where the first impedance element and the second diode are connected to each other and supplies the first impedance element with a current directed toward the reference potential. A switching circuit is connected between the reference potential and the output node of the high-frequency amplification circuit.

### CROSS REFERENCE TO RELATED APPLICATION

This application claims priority from Japanese Patent Application No. 2025-023687, filed on February 17, 2025. The content of these applications are incorporated herein by reference in its entirety.

### BACKGROUND OF THE DISCLOSURE

### Field of the Disclosure

The present disclosure relates to a voltage clamp circuit and a power amplifier.

### DESCRIPTION OF THE RELATED ART

An output current and an output voltage from a high-frequency power amplification circuit largely vary depending on fluctuations of load impedance. There have been demands for high-frequency power amplification circuits to deliver higher output and also to have improved voltage endurance characteristics against load impedance fluctuations. A power amplifier having a voltage clamp circuit inserted between a reference potential and an output node of a high-frequency power amplification circuit to aim for improved voltage endurance characteristics is publicly known (International Publication No. WO2023/210163). The voltage clamp circuit disclosed in International Publication No. WO2023/210163 includes a diode circuit having a plurality of diodes connected in multiple stages and a resistance element connected to the diode circuit in series. The resistance element is formed by part of an epitaxial layer formed on a substrate.

When an excessively high voltage is generated at an output node of the high-frequency power amplification circuit, current flows through the voltage clamp circuit to prevent breakdown of a transistor in the high-frequency power amplification circuit. The breakdown withstand voltage for the transistor in the high-frequency power amplification circuit has temperature dependence, and especially, the breakdown withstand voltage decreases at lower temperatures. To prevent the transistor from breaking down at low temperatures, it is preferable that, at lower temperatures, the voltage clamp circuit is caused to conduct current by a lower voltage.

However, generally, a diode's forward voltage has a negative temperature coefficient, meaning that a diode's forward voltage is higher at lower temperatures. Thus, if the number of stages in the diode circuit is set based on a high temperature at which the breakdown withstand voltage is relatively high, sufficient voltage clamping cannot be performed at lower temperatures, which makes it easier for the transistor to break down.

The resistance value of the resistance element formed at the epitaxial layer used in the voltage clamp circuit described in International Publication No. WO2023/210163 has a positive temperature coefficient. Thus, a voltage drop caused by the resistance element at lower temperatures is small. Thus, connecting the resistance element to the diode circuit in series can mitigate the temperature dependence of the forward voltage of the diode circuit.

### BRIEF SUMMARY OF THE DISCLOSURE

Employing the configuration of the voltage clamp circuit described in International Publication No. WO2023/210163 can mitigate the temperature dependence of the diode circuit's forward voltage to some degree. However, a voltage clamp circuit used for a high-frequency power amplification circuit is required to exhibit characteristics such that a threshold voltage for current conduction be lower at lower temperatures and higher at higher temperatures. It is difficult for the voltage clamp circuit described in International Publication No. WO2023/210163 to exhibit such characteristics.

The present disclosure has a possible benefit to provide a voltage clamp circuit having preferable characteristics for preventing breakdown of a high-frequency amplification circuit. The present disclosure also has a possible benefit to provide a power amplifier having this voltage clamp circuit.

An aspect of the present disclosure provides a voltage clamp circuit including: a first diode circuit including a plurality of first diodes connected in multiple stages, the first diode circuit having an anode-side node connected to an output node of a high-frequency amplification circuit; a second diode having an anode connected to a cathode-side node of the first diode circuit; a first impedance element connected between a cathode of the second diode and a reference potential; a first current source connected to a node where the first impedance element and the second diode are connected to each other, the first current source supplying the first impedance element with a current directed toward the reference potential; and a switching circuit connected between the reference potential and the output node of the high-frequency amplification circuit in which the first current source includes a temperature-dependent element whose electrical characteristics change in accordance with a change in temperature, and supplies the first impedance element with a current having a negative temperature coefficient with respect to a change in temperature of the temperature-dependent element, and the switching circuit includes a control node connected to a node where the first diode circuit and the second diode are connected to each other and conducts current once voltage at the control node exceeds a threshold voltage.

Another aspect of the present disclosure provides a power amplifier including: the voltage clamp circuit; and the high-frequency amplification circuit.

With a decrease in temperature, current flowing through the first impedance element increases, increasing the potential at a node where the second diode and the first impedance element are connected to each other. As a result, voltage at the control node of the switching circuit increases as well. Thus, in a case where voltage at the output node of the high-frequency amplification circuit overly increases, a lower voltage causes the switching circuit to conduct current. Such characteristics of the voltage clamp circuit are preferable because they prevent breakdown of the high-frequency amplification circuit in accordance with a change in temperature.

### BRIEF DESCRIPTION OF THE SEVERAL VIEWS OF THE DRAWINGS

FIG. 1 is a schematic equivalent circuit diagram of a power amplifier having a voltage clamp circuit 30 according to a first embodiment;

FIG. 2A is a graph showing an example relation between a current Icont and the temperature of a temperature-dependent element included in the first current source 35, and FIG. 2B is a graph showing an example relation between temperature and each of voltages V₁ and V₂ when a voltage Vout at the output node 20A of the high-frequency amplification circuit 20 is constant;

FIG. 3 is a graph showing an example relation between a current Ic flowing through a switching circuit 33 and the voltage Vout at the output node 20A;

FIG. 4 is a schematic equivalent circuit diagram of a power amplifier having a voltage clamp circuit 30 according to a second embodiment;

FIG. 5 is a graph showing an example relation between the current Ic flowing through the switching circuit 33 and the voltage Vout at the output node 20A;

FIG. 6 is a schematic equivalent circuit diagram of a power amplifier having a voltage clamp circuit 30 according to a modification of the second embodiment;

FIG. 7 is a schematic equivalent circuit diagram of a power amplifier having a voltage clamp circuit 30 according to a third embodiment;

FIG. 8 is an equivalent circuit diagram of a first current source 35 used in a voltage clamp circuit 30 according to a fourth embodiment; and

FIG. 9 is an equivalent circuit diagram of a voltage clamp circuit according to a modification of the fourth embodiment.

### DETAILED DESCRIPTION OF THE DISCLOSURE

### First Embodiment

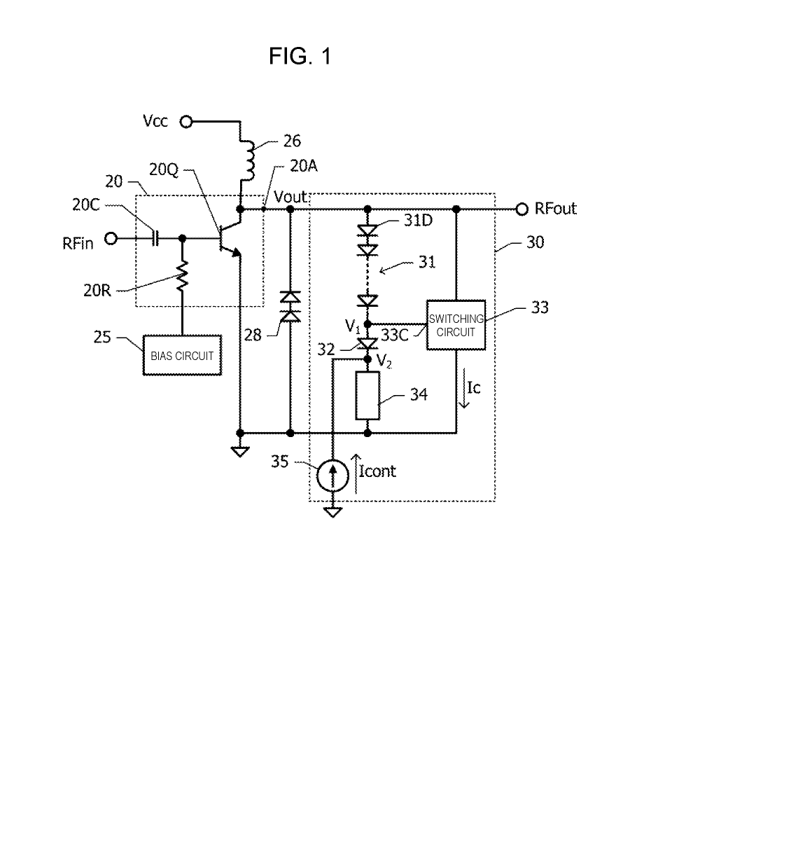

A voltage clamp circuit according to a first embodiment is described with reference to FIGS. 1 to 3.

FIG. 1 is a schematic equivalent circuit diagram of a power amplifier having a voltage clamp circuit 30 according to the first embodiment. The power amplifier includes a high-frequency amplification circuit 20, the voltage clamp circuit 30, and a surge voltage protection circuit 28. The high-frequency amplification circuit Accordingly, using the techniques described herein, a processor includes a matrix unit wherein the arithmetic units are arranged in groups, with each group including a plurality of the arithmetic element units. As used herein, an arithmetic element group is a plurality of arithmetic elements that share circuitry, such as one or more BSRs as described further herein. Arithmetic element groups are sometimes referred to herein as “element groups” for simplicity. The matrix unit further includes a set of BSRs for each arithmetic element group. That is, each arithmetic element group is assigned a different set of BSRs, and each set of BSRs provides the scale factors to the arithmetic elements in its assigned group. This reduces the complexity of the circuity routing (e.g., the routing traces) associated with connecting the BSRs to the corresponding arithmetic elements, thereby conserving power and other system resources. In addition, the overall circuit area consumed by the BSRs is reduced compared to the approach of including a set of BSRs for each arithmetic element.has a configuration such that a plurality of cells are connected in parallel, each cell having a transistor 20Q, an input capacitor 20C, and a ballast resistance element 20R. Only one of the cells is shown in FIG. 1.

For example, a heterojunction bipolar transistor (HBT) is used as the transistor 20Q. A power source voltage Vcc is applied to the collector of the transistor 20Q via a choke coil 26. The emitter of the transistor 20Q is connected to a reference potential. A high-frequency signal RFin is inputted to the base of the transistor 20Q via the input capacitor 20C. A base bias is supplied from a bias circuit 25 to the base of the transistor 20Q via the ballast resistance element 20R. The collector of the transistor 20Q functions as an output node 20A of the high-frequency amplification circuit 20. An amplified high frequency signal RFout is outputted from the output node 20A. The voltage at the output node 20A is denoted as Vout.

The voltage clamp circuit 30 and the surge voltage protection circuit 28 are connected between the reference potential and the output node 20A of the high-frequency amplification circuit 20. The surge voltage protection circuit 28 includes two diodes connected in two stages. The diodes of the surge voltage protection circuit 28 are connected in an orientation that is reverse to the direction from the output node 20A of the high-frequency amplification circuit 20 to the reference potential.

The voltage clamp circuit 30 includes a first diode circuit 31, a second diode 32, a switching circuit 33, a first impedance element 34, and a first current source 35. The first diode circuit 31 includes a plurality of first diodes 31D connected in multiple stages. The anode-side node of the first diode circuit 31 is connected to the output node 20A of the high-frequency amplification circuit 20.

The anode of the second diode 32 is connected to the cathode-side node of the first diode circuit 31. The first impedance element 34 is connected between the reference potential and the cathode of the second diode 32. The first current source 35 is connected between the reference potential and the node where the first impedance element 34 and the second diode 32 are connected to each other. The first current source 35 supplies the first impedance element 34 with a current Icont directed toward the reference potential. The second diode 32 prevents the current Icont supplied from the first current source 35 from flowing into the switching circuit 33. Voltage generated at the node where the first impedance element 34 and the second diode 32 are connected to each other is denoted as V₂.

The first current source 35 includes a temperature-dependent element whose electrical characteristics change in accordance with a change in temperature. The current Icont supplied from the first current source 35 to the first impedance element 34 has a negative temperature coefficient with respect to a change in temperature of the temperature-dependent element. An example of electrical characteristics of a temperature-dependent element is such that with an increase in the temperature of the temperature-dependent element, the current Icont supplied to the first impedance element 34 decreases, and with a decrease in the temperature of the temperature-dependent element, the current Icont supplied to the first impedance element 34 increases.

The temperature-dependent element included in the first current source 35 is thermally coupled to the first diode circuit 31. Thus, the temperature of the temperature-dependent element reflects the temperature of the first diode circuit 31. Specifically, with an increase in the temperature of the first diode circuit 31, the current Icont supplied to the first impedance element 34 decreases, and with a decrease in the temperature of the first diode circuit 31, the current Icont supplied to the first impedance element 34 increases.

The switching circuit 33 is connected between the reference potential and the output node 20A of the high-frequency amplification circuit 20. The switching circuit 33 includes a control node 33C connected to the node where the first diode circuit 31 and the second diode 32 are connected to each other. Voltage generated at the node where the first diode circuit 31 and the second diode 32 are connected to each other is denoted as V₁. The switching circuit 33 conducts current once the voltage V₁ at the control node 33C exceeds a threshold voltage. Current flowing from the output node 20A to the reference potential via the switching circuit 33 is denoted Ic.

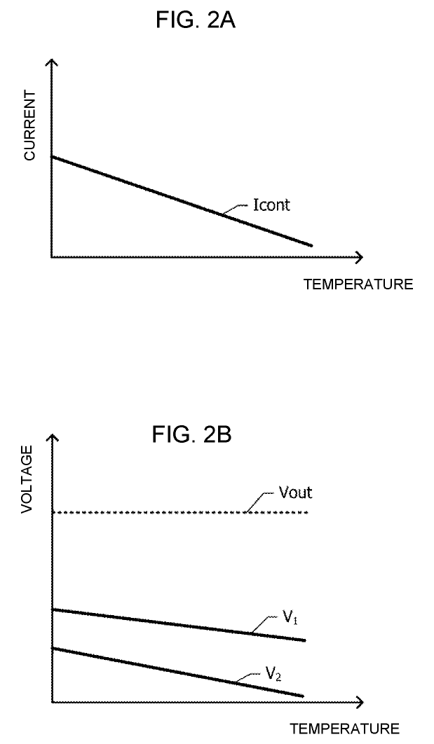

FIG. 2A is a graph showing an example relation between the current Icont and the temperature of the temperature-dependent element included in the first current source 35 (FIG. 1). The horizontal axis represents temperature, and the vertical axis represents current value. The current Icont decreases with an increase in the temperature of the temperature-dependent element, and increases with a decrease in the temperature of the temperature-dependent element.

FIG. 2B is a graph showing an example relation between temperature and each of voltages V₁, V₂ with the voltage Vout at the output node 20A of the high-frequency amplification circuit 20 (FIG. 1) being constant. The horizontal axis represents temperature, and the vertical axis represents voltage value. Note that it is assumed here that the first diode circuit 31 and the second diode 32 are off, and only the current Icont is flowing from the first current source 35 to the first impedance element 34.

With an increase in temperature, the voltage V₂ decreases because the current Icont decreases as shown in FIG. 2A. The voltage V₁ becomes equal to a voltage Vout-V₂ between the output node 20A of the high-frequency amplification circuit 20 and the cathode of the second diode 32, divided by the first diode circuit 31 and the second diode 32. Thus, the voltage V₁ also decreases with an increase in temperature. Also, with an increase in the voltage Vout at the output node 20A, the voltage V₁ increases as well.

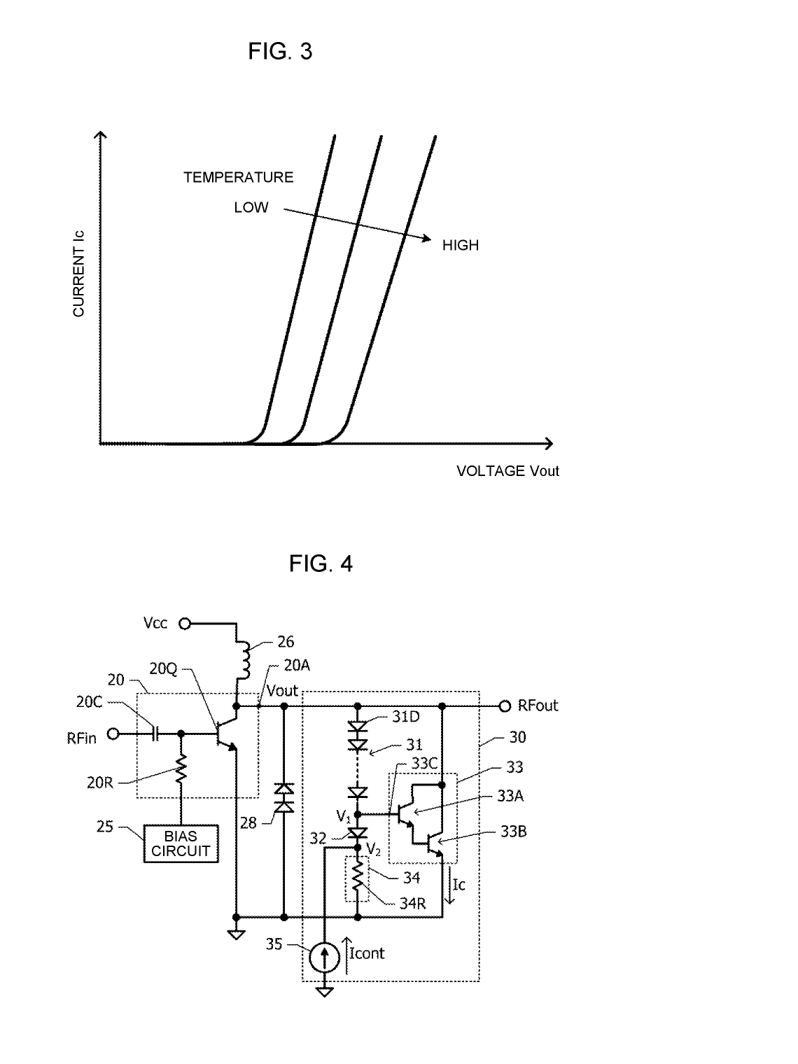

FIG. 3 is a graph showing an example relation between the current Ic flowing through the switching circuit 33 and the voltage Vout at the output node 20A. The horizontal axis represents the voltage Vout at the output node 20A of the high-frequency amplification circuit 20, and the vertical axis represents the current Ic flowing through the switching circuit 33. The three solid lines in the graph shown in FIG. 3 represent the current Ic in respective cases with different temperatures of the temperature-dependent element in the first current source 35.

With an increase in the voltage Vout at the output node 20A, the voltage V₁ increases, and once the voltage V₁ exceeds the threshold voltage for the switching circuit 33, the switching circuit 33 conducts current, causing the current Ic to start flowing. With a decrease in temperature, the voltage V₁ increases as shown in FIG. 2B, and when increasing due to an increase in the voltage Vout, the voltage V₁easily exceeds the threshold voltage for the switching circuit 33. Thus, the voltage Vout at the output node 20A when the current Ic starts flowing is smaller at lower temperatures.

Next, effects achieved by the first embodiment are described.

With an increase in the voltage Vout at the output node 20A in the high-frequency amplification circuit 20 (FIG. 1), the voltage V₁ increases as well, and once the voltage V₁ exceeds the threshold voltage for the switching circuit 33, the switching circuit 33 conducts current. It is possible to help prevent breakdown of the transistor 20Q in the high-frequency amplification circuit 20 by setting the number of stages in the first diode circuit 31, the electric characteristics of the first impedance element 34, the current Icont, and the threshold voltage for the switching circuit 33 so that the switching circuit 33 may conduct current once the voltage Vout at the output node 20A reaches the breakdown withstand voltage for the transistor 20Q.

Further, in the first embodiment, as shown in FIG. 3, the voltage Vout when the current Ic of the switching circuit 33 rises is smaller when the temperature-dependent element in the first current source 35 and the first diode circuit 31 are lower in temperature. Typically, when the temperature decreases, the withstand voltage for the transistor 20Q decreases. Because the voltage Vout when the current Ic of the switching circuit 33 rises is lower at lower temperatures, at which the withstand voltage for the transistor 20Q decreases, the transistor 20Q can be adequately protected at lower temperatures as well.

### Second Embodiment

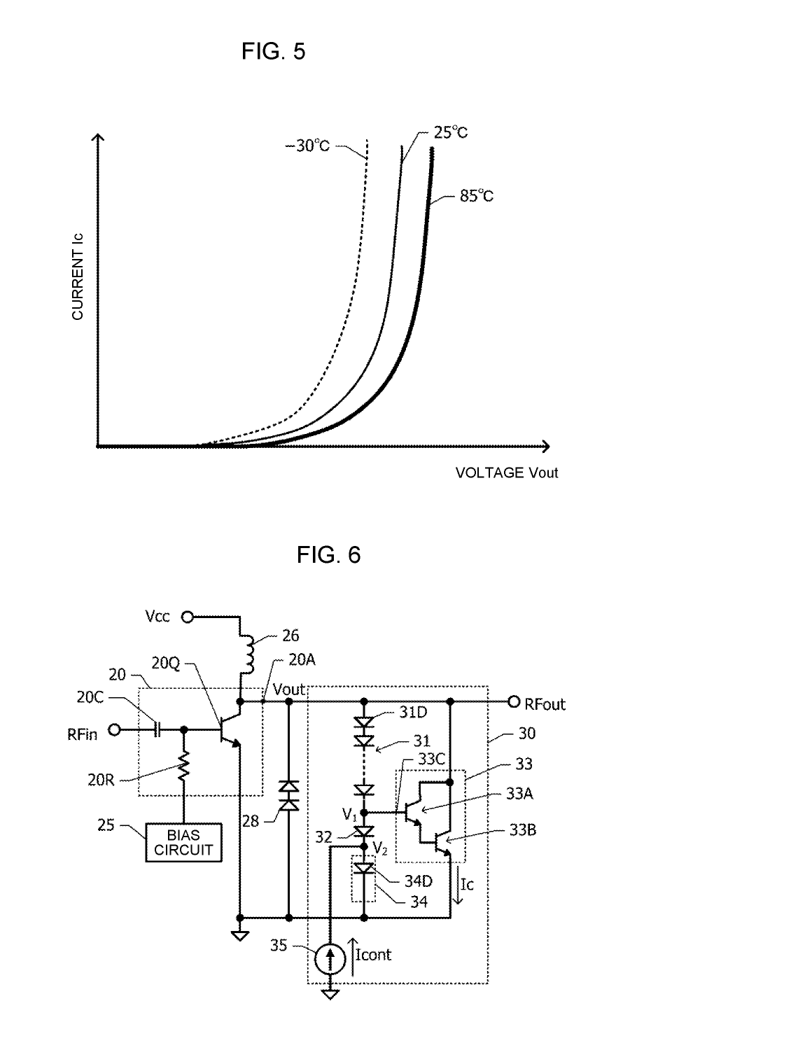

Next, a voltage clamp circuit according to a second embodiment is described with reference to FIGS. 4 and 5. Configurations that are the same as those of the voltage clamp circuit according to the first embodiment described with reference to FIGS. 1 to 3 are not described below.

FIG. 4 is a schematic equivalent circuit diagram of a power amplifier having a voltage clamp circuit 30 according to the second embodiment. In the second embodiment, a Darlington pair circuit having a first transistor 33A and a second transistor 33B is used as the switching circuit 33. HBTs formed by the same compound semiconductor as the transistor 20Q of the high-frequency amplification circuit 20 are used as the first transistor 33A and the second transistor 33B. A resistance element 34R is used as the first impedance element 34. The p-n junction between the first diodes 31D and the second diode 32 is formed of, for example, the same semiconductor material as the base-emitter p-n junction between the first transistor 33A and the second transistor 33B.

The node where the first diode circuit 31 and the second diode 32 are connected to each other is connected to the base of the first transistor 33A. Specifically, the base of the first transistor 33A corresponds to the control node 33C of the switching circuit 33. The collector of the first transistor 33A and the collector of the second transistor 33B are connected to the output node 20A of the high-frequency amplification circuit 20. The emitter of the first transistor 33A is connected to the base of the second transistor 33B. The emitter of the second transistor 33B is connected to the reference potential.

Once the voltage V₁ exceeds the on-voltage for the Darlington pair circuit, the current Ic starts flowing through the switching circuit 33. The base current of the first transistor 33A is (1/h_{FE})² times the current Ic, where h_{FE} is the amplification factor for the current of each of the first transistor 33A and the second transistor 33B, and is sufficiently smaller than the current Ic. Once the switching circuit 33 conducts current, the base current required to turn on the first transistor 33A flows through the first diode circuit 31. Thus, a majority of the current flowing from the output node 20A of the high-frequency amplification circuit 20 to the reference potential passes through the switching circuit 33.

FIG. 5 is a graph showing an example relation between the current Ic flowing through the switching circuit 33 and the voltage Vout at the output node 20A. The horizontal axis represents the voltage Vout at the output node 20A of the high-frequency amplification circuit 20, and the vertical axis represents the current Ic flowing through the switching circuit 33. The thick solid line, the thin solid line, and the broken line in the graph shown in FIG. 5 represent the current Ic in cases where the temperature of the temperature-dependent element in the first current source 35 is 85 °C, 25 °C, and -30 °C, respectively.

The lower the temperature, the lower the voltage Vout when the current Ic starts flowing. Note that GaAs heterojunction bipolar transistors (GaAs-HBTs) are used as the first transistor 33A and the second transistor 33B. N-type bipolar transistors can also be used as the first transistor 33A and the second transistor 33B.

Next, a description is given of the technical significance in using a Darlington pair circuit having the first transistor 33A and the second transistor 33B as the switching circuit 33. When the switching circuit 33 is configured with a single HBT, the base of the HBT receives the total voltage of the voltage V₂ corresponding to the voltage drop caused by the resistance element 34R and the forward voltage of the second diode 32.

This means that a voltage higher than the forward voltage of the second diode 32 is applied to the base of the HBT. Because the voltage for turning on the HBT is almost equal to the forward voltage of the second diode 32, the HBT is on at all times. The voltage for turning on the Darlington pair circuit constituted by the first transistor 33A and the second transistor 33B is approximately double the forward voltage of the second diode 32. Thus, it is possible to turn on and off the switching circuit 33 appropriately by varying the voltage V₂.

Next, effects achieved by the second embodiment are described.

Like the first embodiment, the second embodiment can help prevent breakdown of the transistor 20Q of the high-frequency amplification circuit 20 and also can adequately protect the transistor 20Q at lower temperatures as well.

Next, a voltage clamp circuit of a modification of the second embodiment is described with reference to FIG. 6. FIG. 6 is a schematic equivalent circuit diagram of a power amplifier having a voltage clamp circuit 30 according to the modification of the second embodiment.

While the resistance element 34R is used as the first impedance element 34 in the second embodiment (FIG. 4), in the modification of the second embodiment shown in FIG. 6, a diode 34D is used as the first impedance element 34. The diode 34D is connected in an orientation such that the direction from the second diode 32 to the reference potential is its forward direction. The voltage V₂ fluctuates according to the forward current/voltage characteristics of the diode 34D and the current Icont supplied from the first current source 35. Like in the first embodiment, the voltage V₂ increases with an increase in the current Icont.

As shown in the second embodiment (FIG. 4) and the modification of the second embodiment (FIG. 6), the resistance element 34R or the diode 34D can be used as the first impedance element 34. Besides them, a circuit component having characteristics of causing a larger voltage drop as the current Icont increases can be used as the first impedance element 34. Also, a component with a circuit configuration where a plurality of elements are connected in series or parallel can be used as the first impedance element 34.

Next, another modification of the second embodiment is described. While a Darlington pair circuit constituted by two HBTs is used as the switching circuit 33 (FIG. 4) in the second embodiment, a transistor of a different type, such as a metal-oxide semiconductor field-effect transistor (MOSFET), may be used instead. An adjustment of the threshold voltage for turning on the MOSFET can be made through, for example, an adjustment of the channel dopant profile.

### Third Embodiment

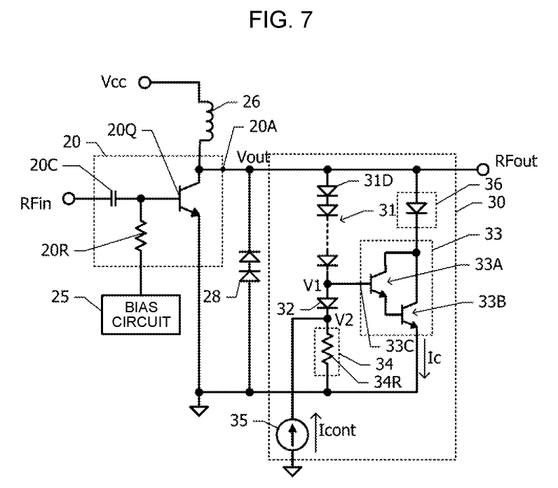

Next, a voltage clamp circuit according to a third embodiment is described with reference to FIG. 7. Configurations that are the same as those of the voltage clamp circuit according to the second embodiment described with reference to FIG. 4 are not described below.

FIG. 7 is a schematic equivalent circuit diagram of a power amplifier having a voltage clamp circuit 30 according to the third embodiment. While the switching circuit 33 is directly connected to the output node 20A of the high-frequency amplification circuit 20 in the second embodiment (see FIG. 4), a second impedance element 36 is connected between the switching circuit 33 and the output node 20A in the third embodiment. For example, a diode is used as the second impedance element 36. The diode is connected in an orientation such that the direction from the output node 20A to the switching circuit 33 is its forward direction.

Next, effects achieved by the third embodiment are described.

In the third embodiment, the current Ic flows through the switching circuit 33 via the second impedance element 36. Because a voltage drop is caused by the second impedance element 36, voltage applied between the collector and emitter of the second transistor 33B of the switching circuit 33 is decreased.

In a configuration where the second impedance element 36 is not connected, voltage almost equal to the voltage Vout at the output node 20A of the high-frequency amplification circuit 20 is applied to the second transistor 33B of the switching circuit 33. Once the voltage Vout exceeds the withstand voltage for the transistor 20Q, the switching circuit 33 conducts current, lowering the voltage Vout, but in a period before the switching circuit 33 conducts current, a voltage exceeding the withstand voltage is temporarily applied to the second transistor 33B.

If the voltage Vout exceeding the withstand voltage is applied only for a short period of time, the second transistor 33B can manage to avoid breaking down albeit the voltage Vout exceeding the withstand voltage. However, if the voltage Vout exceeding the withstand voltage is applied for a long period of time, the risk of the second transistor 33B breaking down rises.

In the third embodiment, the second impedance element 36 causes a voltage drop, reducing the voltage applied to the second transistor 33B. Thus, the second transistor 33B is less likely to break down.

Next, a voltage clamp circuit of a modification of the third embodiment is described.

Although a diode is used as the second impedance element 36 in the third embodiment, an element of a different type that causes a voltage drop, such as a resistance element, may be used instead.

### Fourth Embodiment

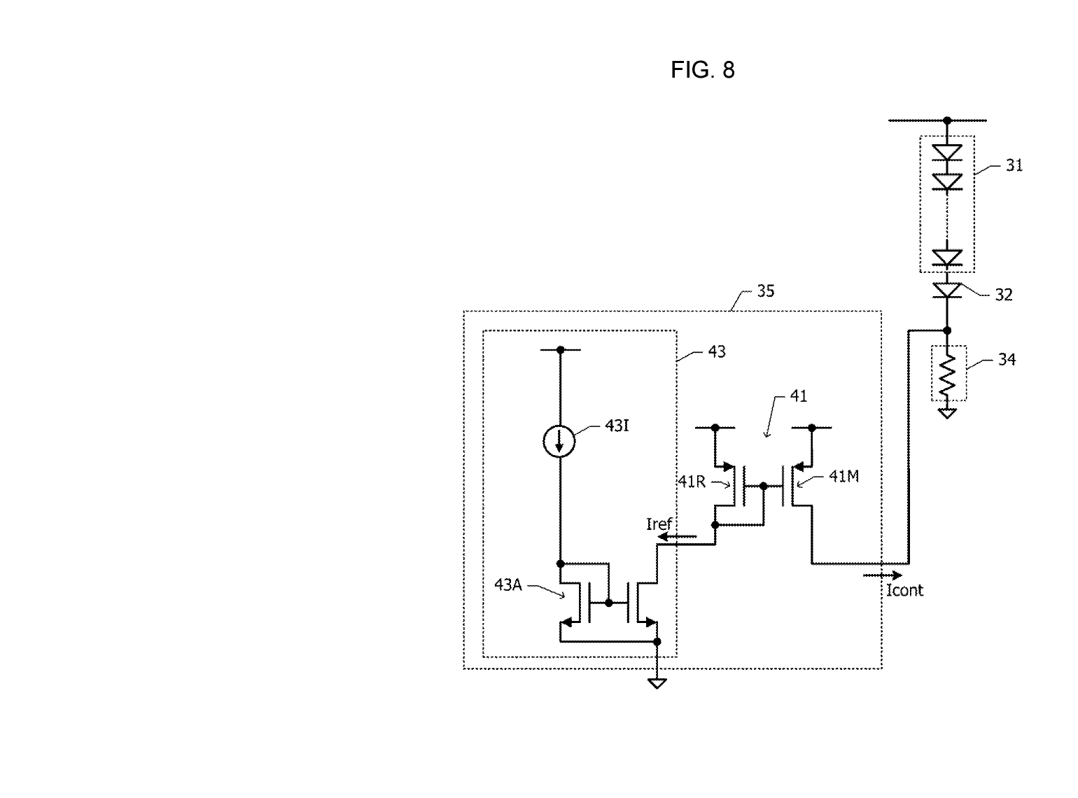

Next, a voltage clamp circuit of a fourth embodiment is described with reference to FIG. 8. Configurations that are the same as those of the voltage clamp circuit of the first embodiment described with reference to FIGS. 1 to 3 are not described below.

FIG. 8 is an equivalent circuit diagram of the first current source 35 used in a voltage clamp circuit 30 according to the fourth embodiment. The first current source 35 includes a current mirror circuit 41 and a second current source 43. The current mirror circuit 41 includes a reference-side transistor 41R through which a reference current Iref flows and a mirror-side transistor 41M through which the current Icont flows. PMOSFETs are used as the reference-side transistor 41R and the mirror-side transistor 41M. The source of the reference-side transistor 41R and the source of the mirror-side transistor 41M are connected to the power source voltage.

The second current source 43 is connected between the reference potential and the drain of the reference-side transistor 41R and passes the reference current Iref directed from the reference-side transistor 41R to the reference potential. The drain of the mirror-side transistor 41M is connected to the first impedance element 34, and the first current source 35 supplies the current Icont to the first impedance element 34.

The second current source 43 includes an NMOS current mirror circuit 43A and a temperature-dependent current source 43I. The temperature-dependent current source 43I generates current dependent on the temperature of the first diode circuit 31. More specifically, with an increase in the temperature of the first diode circuit 31, current generated by the temperature-dependent current source 43I decreases. The current generated by the temperature-dependent current source 43I flows through a reference-side transistor in the NMOS current mirror circuit 43A, and current flowing through a mirror-side transistor serves as the reference current Iref. Thus, the reference current Iref generated by the NMOS current mirror circuit 43A changes depending on the temperature of the first diode circuit 31. The reference current Iref generated by the NMOS current mirror circuit 43A serves as the reference current for the current mirror circuit 41, and the current Icont generated by the current mirror circuit 41 is supplied to the first impedance element 34.

Next, effects achieved by the fourth embodiment are described.

In the fourth embodiment, because the temperature-dependent current source 43I has temperature dependence, the current Icont dependent on temperature as shown in FIG. 2A is generated. This helps prevent breakdown of the transistor 20Q in the high-frequency amplification circuit 20 (FIG. 1) and also enables the transistor 20Q to be adequately protected at lower temperatures as well, like in the first embodiment.

Next, a voltage clamp circuit according to a modification of the fourth embodiment is described.

Although PMOS transistors are used in the current mirror circuit 41 in the fourth embodiment, PNP bipolar transistors may be used instead. In a case of using PNP bipolar transistors, sources, drains, and gates in the above description of the fourth embodiment are read as emitters, collectors, and bases, respectively.

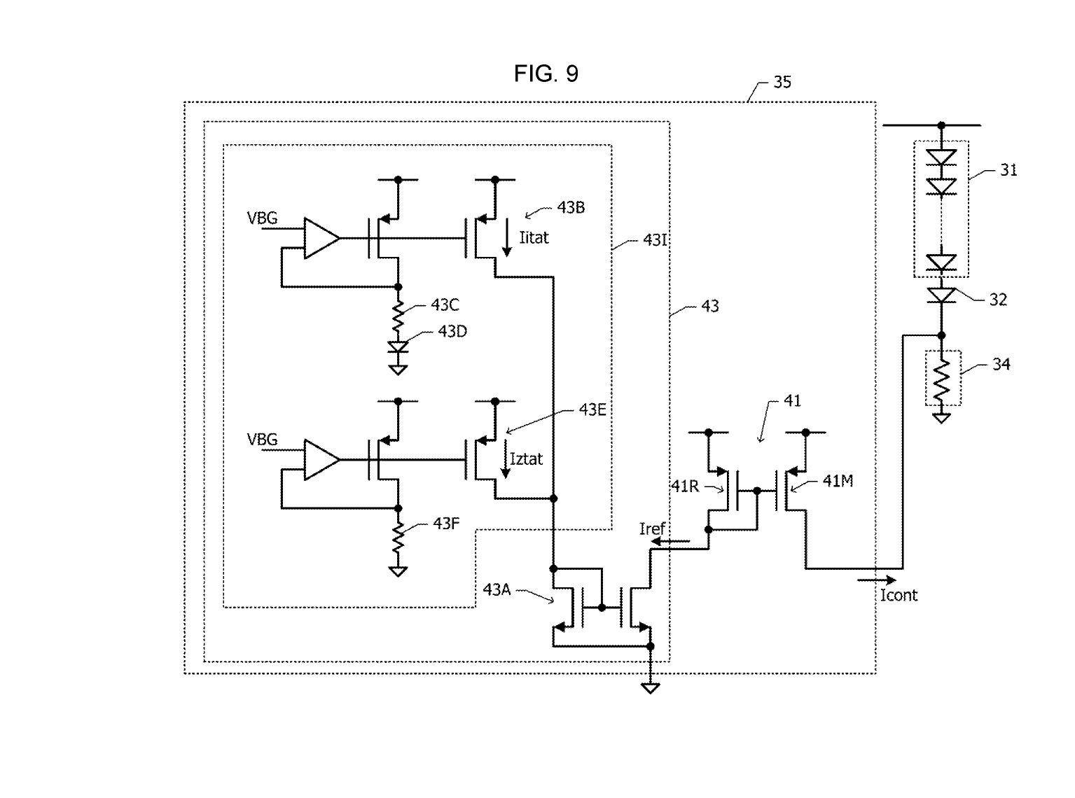

Next, with reference to FIG. 9, a voltage clamp circuit of another modification of the fourth embodiment is described. FIG. 9 is an equivalent circuit diagram of the voltage clamp circuit according to this modification of the fourth embodiment. The modification shown in FIG. 9 shows a specific example of the temperature-dependent current source 43I in the clamp circuit according to the fourth embodiment (FIG. 8).

The temperature-dependent current source 43I includes two PMOS current mirror circuits 43B, 43E. The drain of a reference current-side PMOS transistor in the PMOS current mirror circuit 43B, which is one of the PMOS current mirror circuits 43B, 43E, is connected to the reference potential via a series circuit of a resistance element 43C and a diode 43D. The diode 43D is connected in an orientation such that the direction from the PMOS transistor to the reference potential is its forward direction. The differential voltage between a silicon bandgap voltage VBG and the drain voltage of the PMOS transistor through which the reference current flows is applied to the gates of the two PMOS transistors of the PMOS current mirror circuit 43B.

The forward voltage of the diode 43D is dependent on temperature. In other words, the diode 43D functions as a temperature-dependent element in the first current source 35. An output current Iitat from the PMOS current mirror circuit 43B changes depending on the temperature of the diode 43D. More specifically, with an increase in the temperature of the diode 43D, the output current Iitat decreases.

The diode 43D is thermally coupled with the first diode circuit 31. For example, the first diode circuit 31 and the diode 43D are formed on the same semiconductor substrate. Alternatively, a semiconductor substrate on which the diode 43D is formed may be joined to a semiconductor substrate on which the first diode circuit 31 is formed, or a semiconductor substrate on which the first diode circuit 31 is formed and a semiconductor substrate on which the diode 43D is formed may be mounted on a common module substrate.

The drain of a reference current-side PMOS transistor in the other PMOS current mirror circuit 43E is connected to the reference potential via a resistance element 43F. The differential voltage between the silicon bandgap voltage VBG and the drain voltage of the PMOS transistor through which the reference current flows is applied to the gates of the two PMOS transistors of the PMOS current mirror circuit 43E. An output current Iztat from the PMOS current mirror circuit 43E is not dependent on temperature, but is a constant value based on the resistance value of the resistance element 43F.

The temperature-dependent current source 43I outputs the total current of the output current Iitat and the output current Iztat. This current serves as the reference current for the NMOS current mirror circuit 43A. Thus, the reference current Iref generated by the NMOS current mirror circuit 43A equals the total of the output current Iitat and the output current Iztat. The reference current Iref generated by the NMOS current mirror circuit 43A serves as the reference current for the current mirror circuit 41, and the current Icont generated by the current mirror circuit 41 is supplied to the first impedance element 34.

Next, effects achieved by the modification of the fourth embodiment shown in FIG. 9 are described.

In the modification of the fourth embodiment, the diode 43D thermally coupled with the first diode circuit 31 generates the current Icont with temperature dependence as shown in FIG. 2A. This helps prevent breakdown of the transistor 20Q in the high-frequency amplification circuit 20 (FIG. 1) and also enables the transistor 20Q to be adequately protected at lower temperatures as well, like in the first embodiment.

The embodiments described above are merely exemplary, and it goes without saying that the configurations shown in different embodiments may be partly replaced or combined. The same operational effects achieved by the same configurations in a plurality of embodiments are not described repeatedly. Further, the present disclosure is not restricted by the embodiments described above. It should be apparent to those skilled in the art that, for example, various modifications, alternations, combinations, and the like can be made.

1. A voltage clamp circuit comprising:
a first diode circuit comprising a plurality of first diodes connected in multiple stages, the first diode circuit having an anode-side node connected to an output node of a high-frequency amplification circuit;
a second diode having an anode connected to a cathode-side node of the first diode circuit;
a first impedance circuit element connected between a cathode of the second diode and a reference potential;
a first current source connected to a node where the first impedance circuit element and the second diode are connected to each other, the first current source being configured to supply the first impedance circuit element with a current directed toward the reference potential; and
a switching circuit connected between the reference potential and the output node of the high-frequency amplification circuit,
wherein the first current source comprises a temperature-dependent circuit element whose electrical characteristics change in accordance with a change in temperature,
wherein the first current source is configured to supply the first impedance circuit element with a current having a negative temperature coefficient with respect to a change in temperature of the temperature-dependent circuit element,
wherein the switching circuit has a control node connected to a node where the first diode circuit and the second diode are connected to each other, and
wherein the switching circuit is configured to conduct current once voltage at the control node exceeds a threshold voltage.

2. The voltage clamp circuit according to claim 1, wherein the switching circuit comprises:
a first transistor whose base is the control node, and whose collector is connected to the output node of the high-frequency amplification circuit; and
a second transistor whose base is connected to an emitter of the first transistor, whose collector is connected to the output node of the high-frequency amplification circuit, and whose emitter is connected to the reference potential.

3. The voltage clamp circuit according to claim 1, wherein the first impedance circuit element is either a resistance circuit element or a diode whose forward direction is a direction from the second diode to the reference potential.

4. The voltage clamp circuit according to claim 1, further comprising a second impedance circuit element between the switching circuit and the output node of the high-frequency amplification circuit.

5. The voltage clamp circuit according to claim 1,
wherein the first current source comprises:
a current mirror circuit comprising a reference-side transistor through which a reference current flows and a mirror-side transistor through which an output current flows; and
a second current source,
wherein a source or emitter of the reference-side transistor and a source or emitter of the mirror-side transistor are connected to a power source voltage,
wherein the second current source is connected between the reference potential and a drain or collector of the reference-side transistor, and
wherein a drain or collector of the mirror-side transistor is connected to the first impedance circuit element.

6. The voltage clamp circuit according to claim 1, wherein the temperature-dependent circuit element is thermally coupled with the first diode circuit.

7. A power amplifier comprising:
the voltage clamp circuit according to claim 1; and
the high-frequency amplification circuit.
